(19) United States
(12) Patent Application Publication
(10) Pub. No.: US 2007/0194434 A1
(43) Pub. Date: Aug. 23, 2007

(54) Differential signal transmission structure, wiring board, and chip package

(76) Inventors: Chin-Sung Lin, Hsin-Tien City (TW); Hsing-Chou Hsu, Hsin-Tien City (TW)

Correspondence Address: J.C. Patents, Inc.;Suite 250, 4 Venture, Irvine, CA, 92618, US

(21) Appl. No.: 11/443,764

(22) Filed: May 30, 2006

(30) Foreign Application Priority Data
Feb. 20, 2006 (TW) 95105605

(51) Int. Cl. H01L 23/12

(52) U.S. Cl. 257/700; 257/E23.011

(57) ABSTRACT

A wiring board including a plurality of patterned conductive layers and a plurality of insulating layers is provided. The patterned conductive layers include a first patterned conductive layer and at least one second patterned conductive layer. The first patterned conductive layer has at least one pair of differential signal lines and the second patterned conductive layer has at least one non-wiring area. A projection of the pair of differential signal lines on the second patterned conductive layer at least partially overlaps the non-wiring area. In addition, the insulating layers are disposed between the adjacent patterned conductive layers respectively.

### CROSS-REFERENCE TO RELATED APPLICATION

This application claims the priority benefit of Taiwan application serial no. 95105605, filed on Feb. 20, 2006. All disclosure of the Taiwan application is incorporated herein by reference.

### BACKGROUND OF THE INVENTION

1. Field of Invention

The present invention relates to a differential signal transmission structure, and more particularly, to a wiring board having a differential signal transmission structure and a chip package having the same.

2. Description of Related Art

Generally speaking, the conventional wiring board used for carrying and electrically connecting a plurality of electronic devices is mainly formed by overlapping a plurality of patterned conductive layers and a plurality of insulating layers. The patterned conductive layers are formed by defining the copper foil by lithography and etching processes. The insulating layers are respectively disposed between the adjacent patterned conductive layers for isolating the patterned conductive layers. In addition, the overlapped patterned conductive layers are electrically connected with one another through conductive vias within the wiring board. Further, various electronic devices (e.g., active components or passive components) may be disposed on the surface of the wiring board, and electrical signal propagation is achieved by the wirings within the wiring board.

Referring to FIG. 1, a sectional view of a conventional wiring board is illustrated. A conventional wiring board 100 includes four patterned conductive layers 110, three insulating layers 120, and a plurality of conductive vias 130. A topmost patterned conductive layer 110(a) has a pair of differential signal lines 112 and 114, which are used for transmitting signals of high speed and high frequency. A patterned conductive layer 110(b) located below the topmost patterned conductive layer 110(a) is a ground layer, and the layer 110(b) is used as a reference plane of the pair of differential signal lines 112 and 114. Each insulating layer 120 is disposed between the adjacent patterned conductive layers 110. Each conductive via 130 passes through one of the insulating layers 120. At least two of the patterned conductive layers 110 are electrically connected with each other by one of the conductive vias 130.

If the conventional wiring board 100 is used as the package substrate of a chip package (not shown), the pair of differential signal lines 112 and 114 is used as an intermediate for transmitting signals between the internal wiring of the package substrate and the chip. Thus, the electrical joint of the pair of differential signal lines 112 and 114 with the internal wiring of the package substrate must have matching impedance, and the electrical joint of the pair of differential signal lines 112 and 114 with the chip must also have matching impedance.

However, for the increasing wiring density of the wiring board 100, the distance between the pair of differential signal lines 112 and 114 is reduced. Therefore, when the signals of high-speed and high-frequency are transmitted, the impedance property of the pair of differential signal lines 112 and 114 is influenced. That is, the coupling capacitance of the pair of differential signal lines 112 and 114 increases, so that the impedance of the pair of differential signal lines 112 and 114 is lowered. This leads to impedance mismatch generated between the pair of differential signal lines 112 and 114 and the wirings of other electronic devices (e.g., a chip), and the quality of transmission of the signals of high speed and high frequency by the pair of differential signal lines 112 and 114 is lowered as well. Therefore, for the size shrinkage of products, how to effectively utilize the wiring space of the wiring board to improve the quality of transmission of the signals of high speed and high frequency by the pair of differential signal lines 112 and 114 is an important issue to be solved.

### SUMMARY OF THE INVENTION

The present invention provides a differential signal transmission structure, including at least one pair of differential signal lines and at least one non-wiring area. The pair of differential signal lines and the non-wiring area are not located on the same plane, and a projection of the pair of differential signal lines on the plane of the non-wiring area at least partially overlaps the non-wiring area.

The present invention provides a wiring board, including a plurality of patterned conductive layers and a plurality of insulating layers. The patterned conductive layers include a first patterned conductive layer and at least one second patterned conductive layer. The first patterned conductive layer has at least one pair of differential signal lines, and the second patterned conductive layer has at least one non-wiring area. A projection of the pair of differential signal lines on the second patterned conductive layer at least partially overlaps the non-wiring area. In addition, the insulating layers are disposed between the adjacent patterned conductive layers respectively.

The present invention provides a chip package, including a chip and a package substrate, wherein the chip is electrically connected to the package substrate. The package substrate includes a plurality of patterned conductive layers and a plurality of insulating layers. The patterned conductive layers are alternatively overlapped with each other and include a first patterned conductive layer and at least one second patterned conductive layer. The first patterned conductive layer has at least one pair of differential signal lines, and the second patterned conductive layer has at least one non-wiring area. A projection of the pair of differential signal lines on the second patterned conductive layer at least partially overlaps the non-wiring area. In addition, the insulating layers are disposed between the adjacent patterned conductive layers respectively.

In order to make the aforementioned and other features and advantages of the present invention comprehensible, preferred embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a sectional view of a conventional wiring board.

FIG. 2 shows a side view of a chip package according to the first embodiment of the present invention.

FIG. 3A shows a sectional view of the package substrate of FIG. 2.

FIG. 3B shows a top view of a part of the means of the package substrate of FIG. 3A.

FIG. 4 shows a sectional view of a package substrate according to the second embodiment of the present invention.

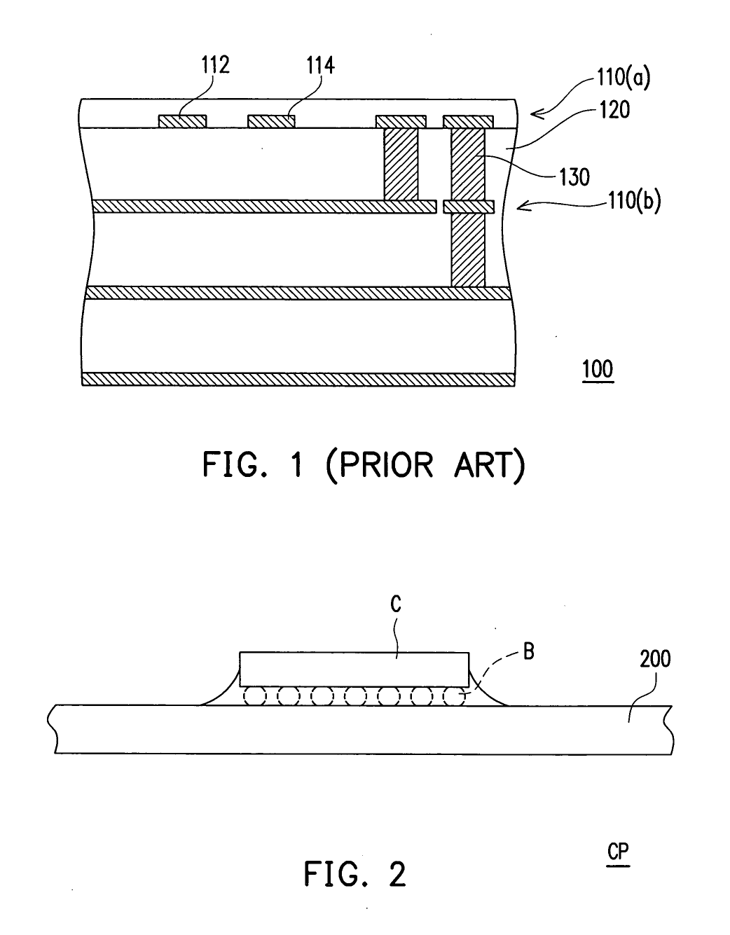

### DESCRIPTION OF EMBODIMENTS

It is known from the description of the prior art that, for increasing wiring density of the wiring board, the distance between the pair of differential signal lines is reduced, so that the coupling capacitance between the pair of differential signal lines is increased. Therefore, the impedance of the pair of differential signal lines is lowered. This leads to impedance mismatch generated between the pair of differential signal lines and the wirings of other electronic devices (e.g., a chip).

Referring to FIG. 2, it shows a side view of a chip package according to a first embodiment of the present invention. The chip package CP of the first embodiment includes a chip C and a package substrate 200. The chip C is disposed on the package substrate 200 and electrically connected to the package substrate 200. As shown in FIG. 2, the chip C is electrically connected to the package substrate 200 by a plurality of bumps B, but it may also be electrically connected to the package substrate 200 by a plurality of conductive wires, which is not shown in the drawing.

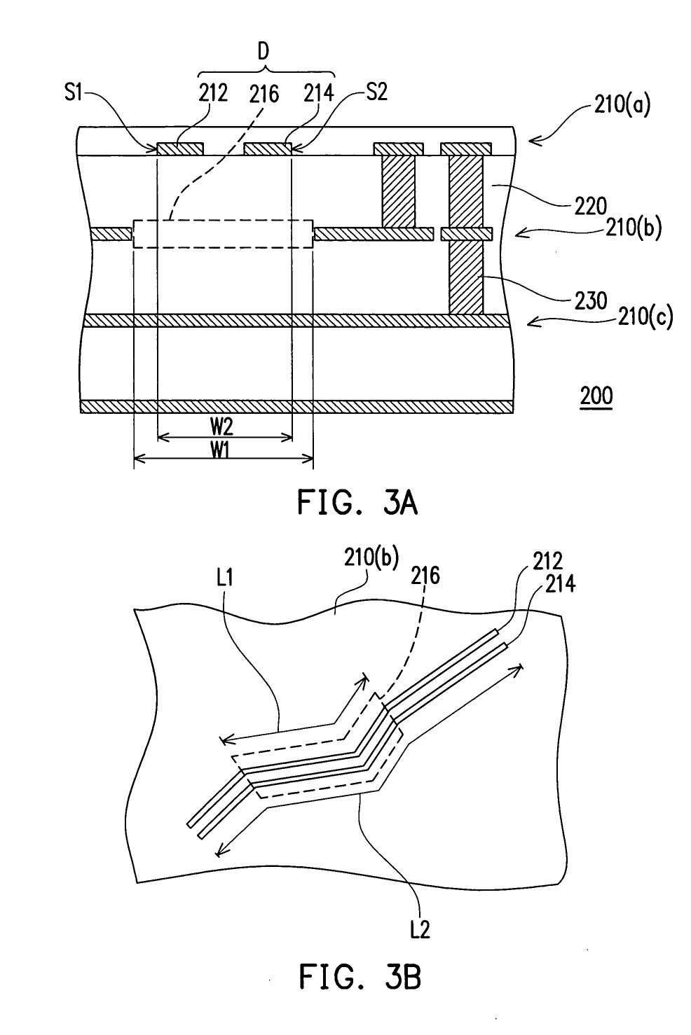

Referring to FIGS. 3A and 3B, FIG. 3A shows a sectional view of the package substrate of FIG. 2, and FIG. 3B shows a top view of part of the means of the package substrate of FIG. 3A. The package substrate 200 of the first embodiment includes a plurality of patterned conductive layers 210, only four of which are schematically shown in FIG. 3A, and a plurality of insulating layers 220, only three of which are schematically shown in FIG. 3A, alternatively overlapping with each other. The insulating layers 220 are disposed between the adjacent patterned conductive layers 210 respectively. That is, the patterned conductive layers 210 and the insulating layers 220 are alternatively overlapped, and the patterned conductive layers 210 include a first patterned conductive layer 210(a) and a second patterned conductive layer 210(b). The first patterned conductive layer 210(a) has at least one pair of differential signal lines 212 and 214, and the second patterned conductive layer 210(b) has at least one non-wiring area 216.

In addition, a projection of the pair of differential signal lines 212 and 214 on the second patterned conductive layer 210(b) at least partially overlaps the non-wiring area 216. In other words, as shown in FIGS. 3A and 3B, the non-wiring area 216 is located below the pair of differential signal lines 212 and 214. Further, the pair of differential signal lines 212 and 214 and the non-wiring area 216 compose a differential signal transmission structure D. The pair of differential signal lines 212 and 214 and the non-wiring area 216 are not on the same plane, and a projection of the pair of differential signal lines 212 and 214 on the plane of the non-wiring area 216 at least partially overlaps the non-wiring area 216.

When the pair of differential signal lines 212 and 214 of the package substrate 200 of the first embodiment transmits signals of high speed and high frequency, due to the non-wiring area 216 of the second patterned conductive layer 210(b) below the pair of differential signal lines 212 and 214, the distance of the electric field between the pair of differential signal lines 212 and 214 and a third patterned conductive layer 210(c) as a reference plane is increased, and the coupling capacitance is lowered. Thus, the impedance of the pair of differential signal lines 212 and 214 of the package substrate 200 of the first embodiment is raised, and the impedance mismatch between the pair of differential signal lines 212 and 214 and the chip C is eliminated. Accordingly, the return loss of the pair of differential signal lines 212 and 214 is raised, and the insertion loss is lowered, so that the quality of transmission of the signals of high-speed and high-frequency by the pair of differential signal lines 212 and 214 is improved. In addition, as the package substrate 200 can reduce the distance between the pair of differential signal lines 212 and 214 by the function of the differential signal transmission structure D mentioned. Thus, the volume of the package substrate 200 can be further reduced while maintaining the quality of the signal transmission of the pair of differential signal lines 212 and 214.

In the first embodiment, the length of one from between the pair of differential signal lines 212 and 214 between two ends of the first patterned conductive layer 210(a) is L2. The length L1 of the projection of the pair of differential signal lines 212 and 214 on the second patterned conductive layer 210(b) overlapping the non-wiring area 216 is, for example, 40% or greater than 40% of the original length L2 of one of the differential signal lines 212 and 214. In other words, the ratio of the overlapped length L1 to the original length L2 is greater than or equal to 0.4. In addition, the width W1 of the non-wiring area 216 of the package substrate 200 may be greater than or equal to the farthest distance W2 between two sides S1 and S2 of the pair of differential signal lines 212 and 214. The second patterned conductive layer 210(b) of the package substrate 200, which has the non-wiring area 216, may be a power layer (power plane) or a ground layer (ground plane). In addition, the package substrate 200 of the first embodiment further includes a plurality of conductive vias 230. Each conductive via 230 passes through one of the insulating layers 220, and at least two of the patterned conductive layers 210 are electrically connected by at least one of the conductive vias 230. Further, the patterned conductive layers 210 are formed, for example, by defining the copper foil by photolithography and etching processes. The material of the insulating layer 220 is, for example, FR-4 or epoxy resin, and the material of the conductive via 230 is, for example, copper.

In the abovementioned first embodiment, the differential signal transmission structure D is applied in the package substrate 200 of a chip package CP. It is necessary to explain here that the differential signal transmission structure D having the greater than-mentioned functions can also be applied in other electrical apparatuses, for example, wiring boards, ceramic substrates, or the wirings of related semiconductor devices.

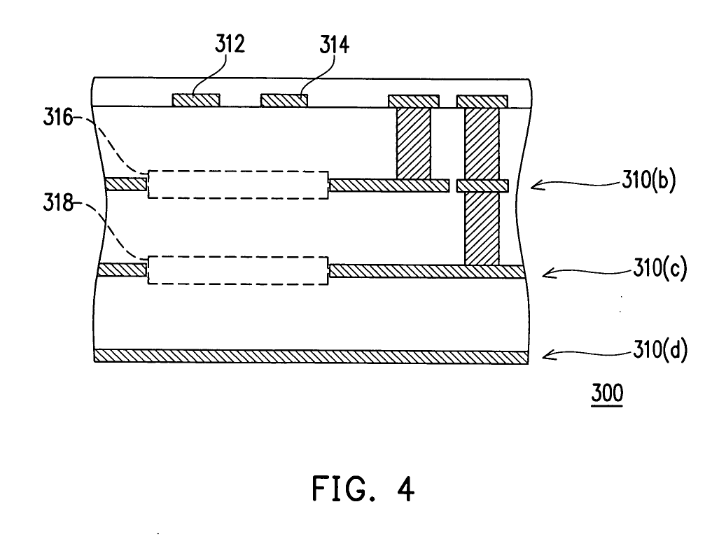

Referring to FIG. 4, it shows a sectional view of a package substrate according to a second embodiment of the present invention. The difference between the second embodiment and the first embodiment is that the second patterned conductive layer 310(b) and the third patterned conductive layer 310(c) of the package substrate 300 of the second embodiment have non-wiring areas 316 and 318 respectively, so that the electric field distance between the pair of differential signal lines 312 and 314 and a fourth patterned conductive layer 310(d) as the reference plane (which may be a power layer or a ground layer) is further increased, and the coupling capacitance is further lowered. Therefore, compared with the first embodiment, the quality of transmission of signals of high speed and high frequency of the pair of differential signal lines 312 and 314 is better.

It must be emphasized here that the patterned conductive layers having non-wiring areas in the first embodiment and the second embodiment are one layer and two layers, respectively. However, in other embodiments, the number of patterned conductive layers having non-wiring areas may vary according to the requirement of designers. In other words, the first embodiment and the second embodiment are used as examples but are not intended to limit the present invention.

In summary, the present invention has the following advantages.

1. Since the distance between the pair of differential signal lines of the differential signal transmission structure is reduced, an electrical apparatus using this differential signal transmission structure can save wiring space.

2. When the wiring board using this differential signal transmission structure transmits signals of high-speed and high-frequency, due to the non-wiring area of the patterned conductive layer below the pair of differential signal lines, the impedance of the pair of differential signal lines is raised. Hence, the quality of transmission of signals of high-speed and high-frequency by the pair of differential signal lines is improved.

3. Since the distance between the pair of differential signal lines of the differential signal transmission structure is reduced, the flexibility of the wiring design is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A differential signal transmission structure, comprising:
at least one pair of differential signal lines on a first plane; and
at least one non-wiring area on a second plane;
wherein a first pair of differential signal lines has a first projection on the second plane, and the first projection overlaps the non-wiring area.

2. The differential signal transmission structure of claim 1, wherein the length of the first projection is equal to 40% or greater than 40% of the length of one of the first pair of differential signal lines.

3. The differential signal transmission structure of claim 1, wherein the width of the non-wiring area is greater than or equal to the distance between the first pair of differential signal lines.

4. A wiring board, comprising:
a plurality of patterned conductive layers, comprising a first patterned conductive layer and at least one second patterned conductive layer, wherein the first patterned conductive layer has at least one pair of differential signal lines, the second patterned conductive layer has at least one non-wiring area, and a first projection of a first pair of differential signal lines on the second patterned conductive layer overlaps the non-wiring area; and
a plurality of insulating layers, disposed between the adjacent patterned conductive layers respectively.

5. The wiring board of claim 4, wherein the length of the first projection is equal to 40% or greater than 40% of the length of one of the first pair of differential signal lines.

6. The wiring board of claim 4, wherein the width of the non-wiring area is greater than or equal to the distance between the first pair of differential signal lines.

7. The wiring board of claim 4, wherein the second patterned conductive layer is a power layer.

8. The wiring board of claim 4, wherein the second patterned conductive layer is a ground layer.

9. The wiring board of claim 4, wherein the wiring board is a circuit board.

10. The wiring board of claim 4, wherein the wiring board is a package substrate.

11. The wiring board of claim 4, further comprising a plurality of conductive vias, wherein each of the conductive vias passes through at least one of the insulating layers.

12. The wiring board of claim 4, further comprising a plurality of conductive vias, wherein at least two of the patterned conductive layers are electrically connected with each other by at least one of the conductive vias.

13. A chip package, comprising:
a chip; and
a package substrate, wherein the chip is disposed on the package substrate and electrically connected to the package substrate, and the package substrate comprises:
a plurality of patterned conductive layers, comprising a first patterned conductive layer and at least one second patterned conductive layer, wherein the first patterned conductive layer has at least one pair of differential signal lines, the second patterned conductive layer has at least one non-wiring area, and a first projection of a first pair of differential signal lines on the second patterned conductive layer overlaps the non-wiring area; and
a plurality of insulating layers, disposed between the adjacent patterned conductive layers respectively.

14. The chip package of claim 13, wherein the length of the first projection is equal to 40% or greater than 40% of the length of one of the first pair of differential signal lines.

15. The chip package of claim 13, wherein the width of the non-wiring area is greater than or equal to the distance between the first pair of differential signal lines.

16. The chip package of claim 13, wherein the second patterned conductive layer is a power layer.

17. The chip package of claim 13, wherein the second patterned conductive layer is a ground layer.

18. The chip package of claim 13, further comprising a plurality of conductive vias, wherein each of the conductive vias passes through at least one of the insulating layers, and at least two of the patterned conductive layers are electrically connected with each other by at least one of the conductive vias.

19. The chip package of claim 13, further comprising a plurality of bumps, wherein the chip is electrically connected to the package substrate by the bumps.

20. The chip package of claim 13, further comprising a plurality of conductive wires, wherein the chip is electrically connected to the package substrate by the conductive wires.
